(19) United States
(12) Patent Application Publication
(10) Pub. No.: US 2025/0370348 A1
(43) Pub. Date: Dec. 4, 2025

(54) STORAGE MEDIUM, LITHOGRAPHY METHOD, INFORMATION PROCESSING APPARATUS, LITHOGRAPHY APPARATUS, AND ARTICLE MANUFACTURING METHOD

(71) Applicant: CANON KABUSHIKI KAISHA, Tokyo (JP)

(72) Inventor: AYANE HIROTA, Tochigi (JP)

(21) Appl. No.: 19/206,395

(22) Filed: May 13, 2025

(30) Foreign Application Priority Data
May 29, 2024 (JP) 2024-087246

(51) Int. Cl. G03F 7/00; G03F 9/00

(52) U.S. Cl. CPC G03F 7/70475; G03F 7/70258; G03F 7/70358; G03F 7/70533; G03F 7/70725; G03F 9/7003; G03F 9/7092

(57) ABSTRACT

A computer-readable storage medium storing a program for causing a computer to execute a method for generating control information on a lithography apparatus is provided. The lithography apparatus is configured to correct at least one of first and second shot regions of a substrate such that an outer peripheral portion of the first shot region and an outer peripheral portion of the second shot region match at least at one point. The program causes the computer to execute obtaining information on a deviation amount with respect to an ideal shape of a shot region of a lower layer, and generating control information including correction information for correcting a higher-order shape of the at least one of the first and second shot regions to be formed at an upper layer based on information on the deviation amount.

### BACKGROUND

### Field of the Technology

The present disclosure relates to a storage medium, a lithography method, an information processing apparatus, a lithography apparatus, and an article manufacturing method.

### Description of the Related Art

Known exposure methods include a method for, when exposing a large substrate in particular, not exposing an exposure region on the substrate at once but dividing the exposure region into several shot regions. In that case, the connection state of adjacent shot regions is no longer good due to distortion of the shot regions caused by the influence of an exposure error, and the electrical characteristics of a chip can be adversely affected.

To address this problem, there is a technique of correcting an exposure condition so that a connection state of a plurality of shot regions adjacent to each other becomes continuous. For example, Japanese Patent Laid-Open No. 2017-090817 discloses a method for improving a connection state by correcting exposure control information based on a connection state of a plurality of shot regions adjacent to each other.

According to the method disclosed in Japanese Patent Laid-Open No. 2017-090817, it is possible to perform correction when a connecting portion of adjacent shot regions has a linear shape. However, when the connecting portion is non-linear and has a higher-order shape of second or higher order, good correction cannot be performed. In recent years, demand for the electrical characteristics of the chip has further increased, and when the exposure region is divided into a plurality of shot regions and exposed, it is necessary to further improve the connection state between the shot regions.

### SUMMARY

The present disclosure provides an advantageous technique for improving a connection state between adjacent shot regions.

The present disclosure in its one aspect provides a computer-readable storage medium storing a program for causing a computer to execute a method for generating control information on a lithography apparatus that transfers a pattern to a substrate, wherein the lithography apparatus is configured to correct at least one of a first shot region and a second shot region of the substrate such that an outer peripheral portion of the first shot region and an outer peripheral portion of the second shot region match at least at one point, and the program causes the computer to execute obtaining information on a deviation amount with respect to an ideal shape of a shot region of a lower layer formed on the substrate, and generating control information including correction information for correcting a higher-order shape of the at least one of the first shot region and the second shot region to be formed at an upper layer based on information on the deviation amount.

Features of the present disclosure will become apparent from the following description of embodiments with reference to the attached drawings. The following description of embodiments are described by way of example.

### BRIEF DESCRIPTION OF THE DRAWINGS

The accompanying drawings, which are incorporated in and constitute a part of the specification, illustrate embodiments of the present disclosure, and together with the description, serve to explain the principles of the embodiments.

FIG. 1 is a view illustrating a configuration of an exposure apparatus.

FIGS. 2A to 2D are views for explaining a known method for shape correction of a shot region.

FIGS. 3A and 3B are views illustrating a concept of shape correction of a shot region.

FIGS. 4A to 4C are views illustrating a specific example of shape correction of a shot region.

FIG. 5 is a view illustrating an operation flow of an exposure apparatus.

FIG. 6 is a view for explaining how to obtain a correction parameter.

FIGS. 7A to 7I are views illustrating examples of initial coordinate values of a shot region A.

FIG. 8 is a view illustrating an example of a calculation result of a parameter for improving a connection state of a shot region.

FIGS. 9A and 9B are views illustrating examples before and after improvement of a connection state of a shot region.

FIGS. 10A and 10B are views illustrating a concept of shape correction of a shot region.

FIG. 11 is a flowchart of a method for generating control information.

FIG. 12 is a view illustrating an example of a plurality of shot regions and a scribe line region.

FIG. 13 is a view for explaining stitching exposure.

FIG. 14 is a view for explaining overlay of upper and lower layers in stitching exposure.

### DESCRIPTION OF THE EMBODIMENTS

Hereinafter, embodiments will be described in detail with reference to the attached drawings. Note, the following embodiments are not intended to limit the scope of the claims. Multiple features are described in the embodiments, but it is not the case that all such features are required, and multiple such features may be combined as appropriate. Furthermore, in the attached drawings, the same reference numerals are given to the same or similar configurations, and redundant description thereof is omitted.

### First Embodiment

The present disclosure relates to a lithography apparatus that performs lithography processing of transferring a pattern to a substrate. The lithography apparatus can be, for example, an exposure apparatus, an imprint apparatus, an electron beam drawing apparatus, or the like. Hereinafter, in order to provide a specific example, an embodiment when the lithography apparatus is an exposure apparatus will be described.

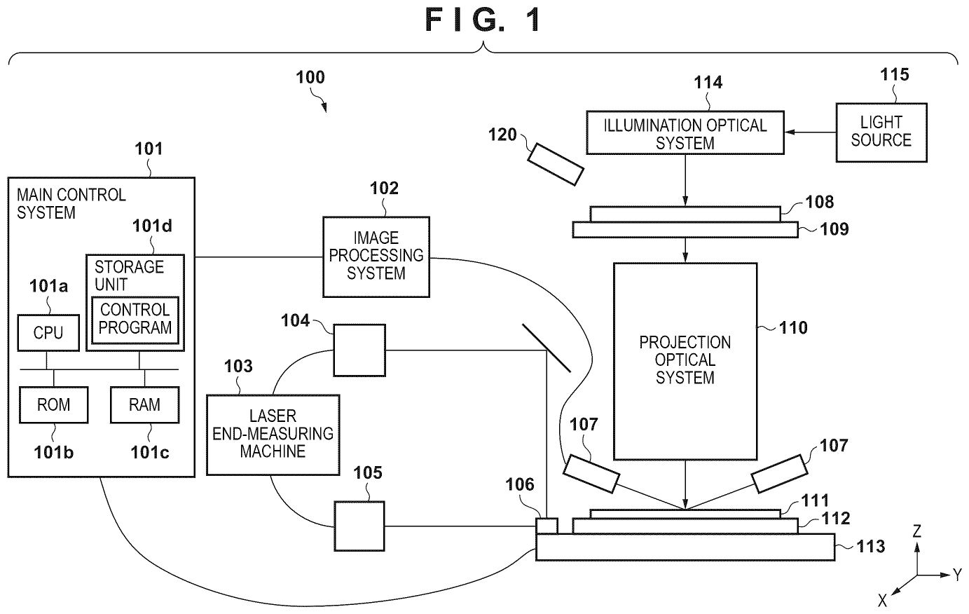

FIG. 1 is a schematic diagram of an exposure apparatus 100 in an embodiment. In the present description and the drawings, directions are indicated in an XYZ coordinate system where a horizontal plane is an XY plane. In general, a substrate 111, which is a substrate to be exposed, is placed on a substrate stage 113 such that the surface thereof is parallel to the horizontal plane (XY plane). Therefore, in the following description, directions orthogonal to each other in a plane along the surface of the substrate 111 are defined as an X axis and a Y axis, and a direction perpendicular to the X axis and the Y axis is a Z axis. Hereinafter, directions parallel to the X axis, the Y axis, and the Z axis in the XYZ coordinate system are called an X direction, a Y direction, and a Z direction, respectively, and a rotational direction around the X axis, a rotational direction around the Y axis, and a rotational direction around the Z axis are called a OX direction, a OY direction, and a OZ direction, respectively.

An original stage 109 holds an original 108 (mask, reticle). The original 108 held by the original stage 109 is irradiated with light from a light source 115 by an illumination optical system 114. The projection optical system 110 projects light transmitted through the original 108 onto the substrate 111 (wafer). At this time, the substrate 111 is held by a substrate holding unit 112 (substrate chuck). The substrate holding unit 112 is supported by the substrate stage 113 configured movably.

The substrate stage 113 includes a six-axis drive mechanism that drives in each direction of X, Y, Z, OX, OY, and OZ, for example, and is driven based on an instruction value from a main control system 101. The current position of the substrate stage 113 is obtained by measuring reflected light of light emitted from laser heads 104 and 105 to a mirror 106 on the substrate stage by a laser end-measuring machine 103 and converting the reflected light into an attitude amount. The main control system 101 obtains a current position of the substrate stage 113 from the laser end-measuring machine 103, generates a new drive instruction value, and applies feedback to maintain the attitude of the substrate stage 113.

A focus sensor 107 includes a light projecting unit and a light receiving unit installed in the Y direction so as to sandwich the vicinity of an emitting unit of the projection optical system 110, irradiates the substrate 111 with obliquely incident light from the light projecting unit at a prescribed pitch following scanning exposure, and takes in the light reflected by the substrate with the light receiving unit. An image processing system 102 calculates a Z displacement amount based on the light amount taken in with the light receiving unit. The main control system 101 calculates an approximate plane from the Z displacement amount at each point in a region. Thereafter, the main control system 101 changes drive instruction values of Z, OX, and OY of the substrate stage 113 so that the surface of the substrate 111 matches a projection image of the original 108 projected through the projection optical system 110.

An alignment measurement unit 120 measures a relative positional deviation between the original 108 and the substrate 111. Here, the alignment measurement unit 120 can measure coordinates of a predetermined position for each of a plurality of regions (a plurality of shot regions). Alignment marks can be formed at predetermined positions (e.g., four corners and five points at the center) of each shot region, for example, but are not limited to these.

The main control system 101 is a control unit that integrally controls each unit of the exposure apparatus 100. The main control system 101 can include a computer (information processing apparatus). The main control system 101 may include, for example, a CPU 101a, a ROM 101b that holds a boot program and fixed data, and a RAM 101c that provides a work area of the CPU 101a and holds temporary data. The main control system 101 can include a storage unit 104d including a control program for performing lithography processing. In the present embodiment, the main control system 101 also functions as a generation unit (obtaining unit) that generates (obtains) control information (e.g., shot layout information, projection magnification, scan direction, and the like) related to exposure.

In the present embodiment, the exposure apparatus 100 can be a scanning exposure apparatus that performs exposure while relatively driving the original and the substrate. In manufacturing of a semiconductor device, generally, a plurality of layers each having a pattern formed are overlaid on a substrate. Each of the plurality of layers is overlaid while being aligned with respect to a lower layer. That is, exposing is performed such that a second layer (upper layer) having a pattern formed by second exposure is overlaid on a first layer (lower layer) having a pattern formed on the substrate by first exposure.

In recent years, for example, an increase in size of a display such as a liquid crystal panel has progressed, and it is necessary to expose a glass substrate exceeding a square that is 2 meters long and wide. In order to cope with such an increase in size of the substrate, not exposing the entire exposure region on the substrate at once but dividing the exposure region on the substrate into several shot regions and exposing the shot regions. In this case, for example, exposure is controlled such that the joint between the first shot region and the second shot region is continuous. Such exposure is called “stitching exposure”.

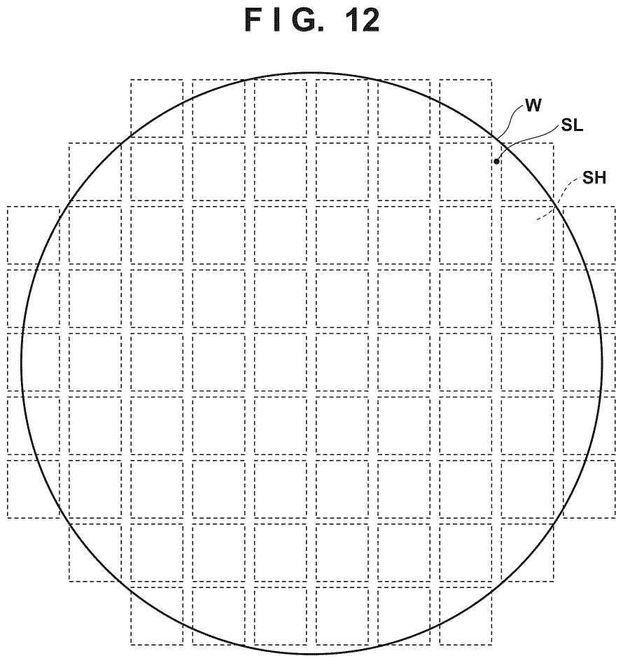

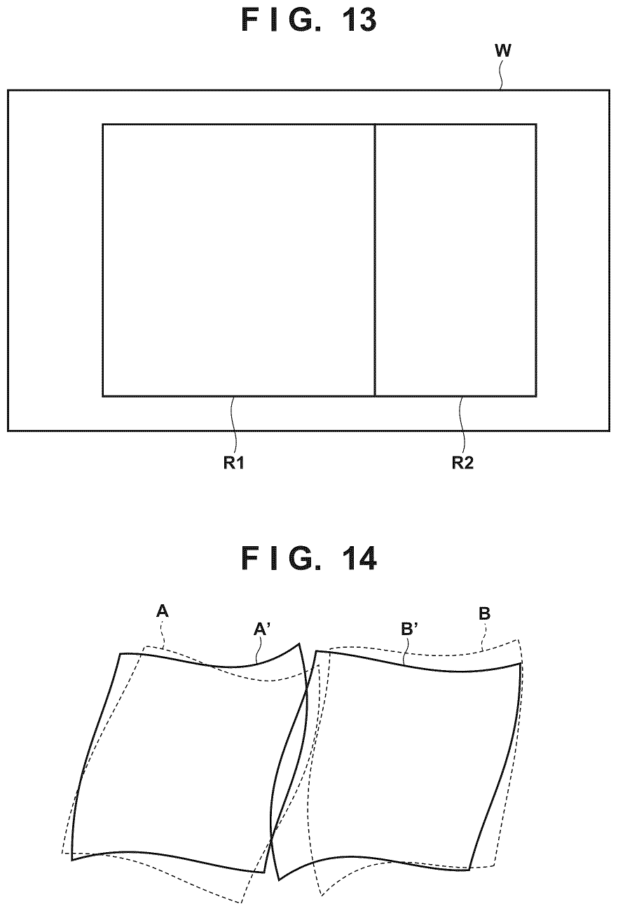

In the case of a substrate on which general exposure is performed, a scribe line to be cut when the chip is diced can be interposed between adjacent shot regions. For example, as illustrated in FIG. 12, a plurality of shot regions SH and a scribe line SL separating the plurality of shot regions from each other can be formed on a substrate W (circular substrate in the example of FIG. 12). In general, since the scribe line SL is to be cut, a pattern to be a product is not formed therein. However, an alignment mark or the like can be formed on the scribe line SL.

On the other hand, in stitching exposure, pattern transfer (exposure) is performed such that the joint between the first shot region and the second shot region of the substrate is continuous. The phrase “joint is continuous” refers to a state where adjacent sides of the first shot region and the second shot region are close to each other, and the outer peripheral portion of the first shot region and the outer peripheral portion of the second shot region match at least at one point. Therefore, in stitching exposure, at least one of the first shot region and the second shot region of the substrate is corrected such that the outer peripheral portion of the first shot region and the outer peripheral portion of the second shot region match at least at one point. This can be achieved, for example, by performing exposure such that the first shot region R1 and the second shot region R2 are adjacent to each other not via a scribe line in the substrate W (rectangular substrate in the example of FIG. 13) as illustrated in FIG. 13. Therefore, the main control system 101 can function as a control unit that performs control processing of pattern transfer (exposure) such that the joint between the first shot region and the second shot region is continuous in accordance with control information for performing stitching exposure.

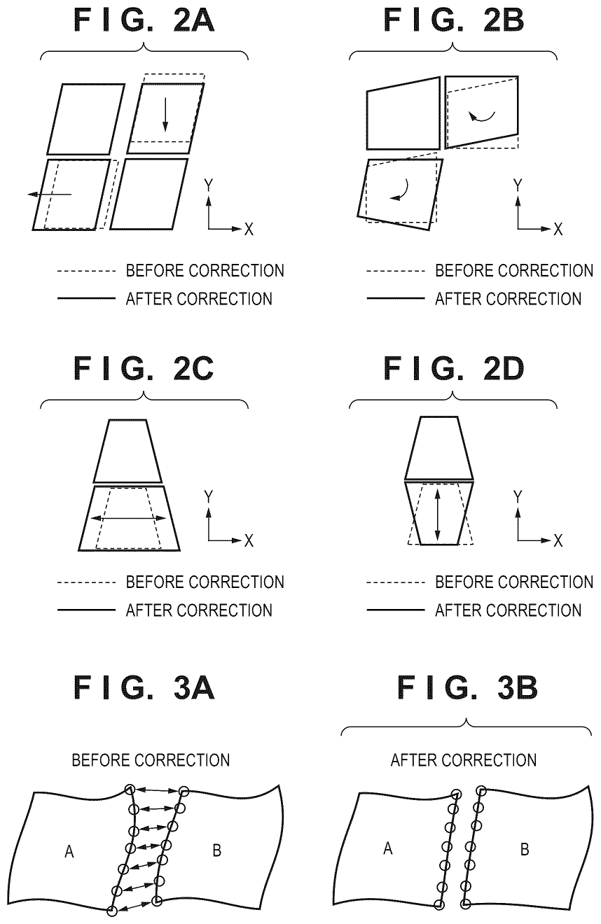

In FIG. 14, shot regions A′ and B′ indicated by solid lines are shot regions formed in the lower layer by stitching exposure, and shot regions A and B indicated by broken lines indicate shot regions to be overlaid on an upper layer by the stitching exposure. In the shot regions A′ and B′ of the lower layer, non-linear distortion has been caused by the process. The shot regions A and B of the upper layer should be accurately overlaid on the shot regions A′ and B′ of the lower layer in which this nonlinear distortion is occurring, respectively. In addition, the positional deviation between the shot region A and the shot region B adjacent to each other in the same layer should be accurately corrected. According to a known technique of stitching exposure, when the connection state between the shot region A and the adjacent shot region B is low order (linear shape), the connection state can be improved by correcting information for controlling the shape of the exposure region. FIGS. 2A to 2D illustrate a correction method for a shot region that can improve a low-order connection state. The connection state of the shot region is improved by combining one or more of the methods illustrated in FIGS. 2A to 2D for at least any of the plurality of shot regions so that the sides to be connected match each other. Here, FIG. 2A illustrates shift of the shot region, FIG. 2B illustrates rotation of the shot region, FIG. 2C illustrates magnification of the shot region, and FIG. 2D illustrates reversal of the scan direction of the exposure. However, in practice, the shape of a shot region changes due to a process error. Here, like the shot region A and the shot region B indicated as “before correction” in FIG. 3A, at least one side usually has a higher order (second or higher order) shape rather than a linear shape. Therefore, a known improvement method cannot completely correct a higher-order shape in a connection state.

According to the present embodiment, as described below, the connection state between the shot region A and the shot region B is improved without causing a decrease in throughput. In the present embodiment, by correcting the higher-order shape of at least one of the shot region A and the shot region B, the connection state between the shot region A and the shot region B is improved as illustrated as “after correction” in FIG. 3B.

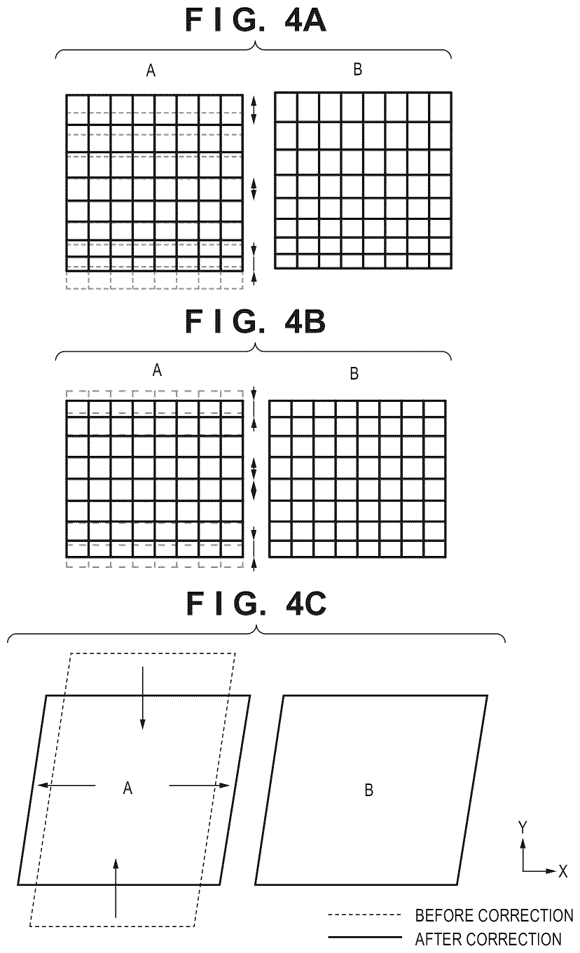

A method for improving a higher-order connection state between the shot region A and the shot region B adjacent to each other will be described with reference to FIGS. 4A to 4C. FIGS. 4A to 4C illustrate examples of a case of improving the connection state by correcting the shape of the shot region A with respect to the shot region B.

FIG. 4A illustrates an example of second-order distortion in the Y direction of the shot region. In this case, the connection state between the shot region A and the shot region B can be improved by each point in the lattice of the shot region A being moved by a first amount in the Y direction. FIG. 4B illustrates an example of third-order distortion in the Y direction of the shot region. In this case, the connection state between the shot region A and the shot region B can be improved by each point in the lattice of the shot region A moving by a second-order amount in the Y direction. FIG. 4C illustrates an example of a horizontal and/or vertical magnification difference of the shot region. In this case, the connection state between the shot region A and the shot region B can be improved by controlling the projection optical system so as to change the horizontal and/or vertical magnification of the shot region A. Here, examples of the second-order and third-order distortion correction in the Y direction of the shot region has been described, but the second-order and third-order distortion corrections in the X direction of the shot region may be performed.

The improvement method illustrated in each of FIGS. 2A to 2C and FIGS. 4A to 4C is a method for correcting the shape of the shot region, and is a method for controlling a correction parameter unique to one shot region. A unique correction parameter may be shift, rotation, magnification, distortion, or the like of the shot region. In the present embodiment, when the first exposure is performed by the scanning exposure apparatus, it is also possible to control a plurality of correction parameters for one shot region, such as changing the correction parameters in accordance with elapsed exposure time during scanning exposure.

An example of performing shape correction on the shot region A at the time of exposure has been described above. However, correction may be performed at the time of exposure of the shot region B, or correction may be performed both at the time of exposure of the shot region A and at the time of exposure of the shot region B. A plurality of combinations of correction parameters may be used. In the above example, the example of improving the connection state for the two shot regions has been described, but the connection state can be improved by a similar method even for three or more shot regions. The correction parameter used in the first exposure is determined such that the joint of the shot regions becomes continuous, for example, based on the shot region shape in test exposure obtained in advance.

### Example 1

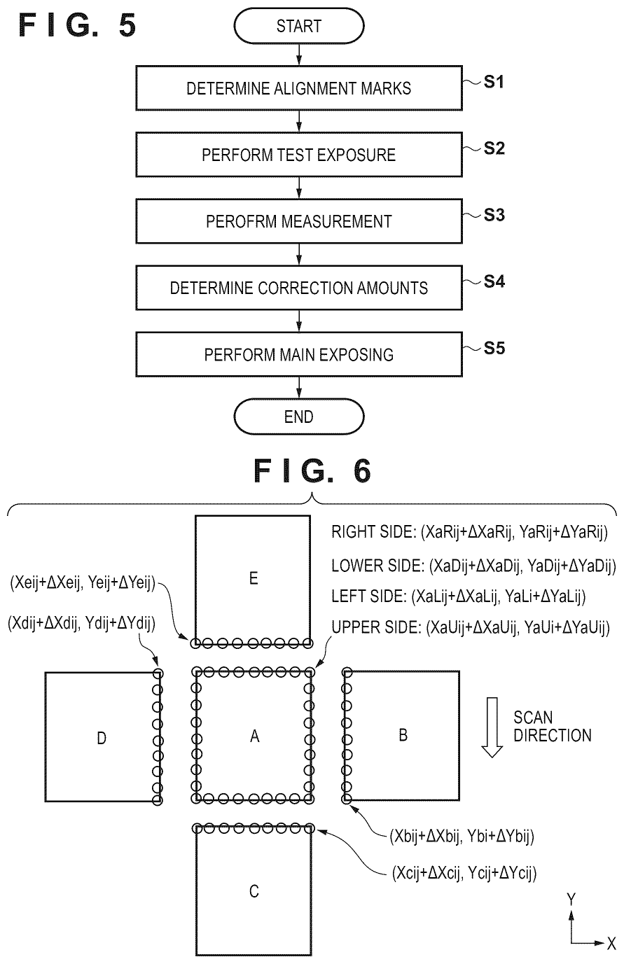

FIG. 5 is a flowchart of an exposure method (lithography method) by the exposure apparatus 100 according to the present example.

In S1, the main control system 101 (CPU 101a) determines a plurality of alignment marks to be used on an assumption that the shape of the shot region is ideal.

In S2, the main control system 101 executes test exposure for exposing a test substrate using the plurality of alignment marks determined in S1. By this, one or more shot regions of the lower layer are formed.

In S3, the main control system 101 measures coordinates of a plurality of alignment marks formed on the test substrate using an alignment measurement unit 120 for each shot region in the test exposure in S2.

In S4, the main control system 101 obtains information on a deviation amount with respect to an ideal shape of each shot region of the lower layer (obtaining). This can be performed by obtaining information on a deviation amount from an ideal position of each of the plurality of alignment marks arranged on the substrate for each shot region based on the result of the measurement in S3, for example. The main control system 101 determines correction information for making a joint between the shot region A (first shot region) and the shot region B (second shot region) to be formed in the upper layer continuous based on the information on the deviation amount having been obtained. Details of this processing will be described later. In this S4, the main control system 101 generates correction information for correcting a higher-order shape of at least one of the shot regions A and B to be formed in the upper layer based on the information on the deviation amount with respect to the ideal position of the shot region of the lower layer (generating). The main control system 101 includes the generated correction information into the control information.

S5 is processing (main exposing) in which the main control system 101 performs stitching exposure in accordance with the control information including the correction information determined in S4. In the stitching exposure, exposure of the shot region A and the shot region B is performed such that at least one of the shot region A and the shot region B is corrected such that the outer peripheral portion of the shot region A and the outer peripheral portion of the shot region B match at least at one point.

With reference to FIG. 6, how to obtain a correction parameter (correction information) for making a joint between the shot region A and four shots therearound continuous will be described. Here, the correction parameter can be at least any of shift, rotation, magnification, distortion, and a horizontal or vertical magnification difference of the shot region A. In a case where the exposure apparatus 100 is a scanning exposure apparatus, in addition to the above parameters, the correction parameter can be at least any of shift, rotation, magnification, and distortion of the shot region during scanning exposure. The main control system 101 is assumed to control at least any of the projection optical system 110 and the substrate stage 113 such that the correction parameter is adjusted based on the correction information.

In FIG. 6, a point of interest of the joint of the shot region is four sides of the shot region A and four sides connected to the shot region A of the shot regions B, C, D, and E. Here, the coordinates of these ideal positions are (XaRij, YaRij), (XaDij, YaDij), (XaLij, YaLij), (XaUij, YaUij), (Xbij, Ybij), (Xcij, Ycij), (Xdij, Ydij), and (Xeij, Yeij). However, the center position of the shot region A is (0,0), and the subscripts i and j indicate each point position of the shot region. For example, i takes a value of integers 1 to 9 in the X direction, and j takes a value of integers 1 to 9 in the Y direction. The direction of scanning exposure is assumed to be in the Y direction.

Here, focusing on the right side of the shot region A and the left side of the shot region B, the coordinates of each point before connection state improvement are defined as follows.
Shot region A right side (i=9, j=1 to 9): (XaRij+ΔXaRij, YaRij+ΔYaRij)·
Shot region B left side (i=9, j=1 to 9): (Xbij+ΔXbij, Ybij+ΔYbij) where
   ΔXaRij is a deviation amount in the X direction of the coordinates at the i,j position on the right side of the shot region A at the time of test exposure,
   ΔYaRij is a deviation amount in the Y direction of the coordinates at the i,j position on the right side of the shot region A at the time of test exposure,
   ΔXbij is a deviation amount in the X direction of the coordinates at the i,j position on the left side of the shot region B at the time of test exposure, and
   ΔYbij is a deviation amount in the Y direction of the coordinates at the i,j position on the left side of the shot region B at the time of test exposure.

For these deviation amounts, a value converted into a deviation amount at each point of the shot region based on the deviation amount from the ideal position of one or more alignment marks is used. Alternatively, a value obtained by measuring the baking result of the test exposure by an external apparatus or an internal apparatus and directly measuring the deviation amount from the ideal position of each point is used as the deviation amount. Conversion into the deviation amount at each point of the shot region based on the deviation amount from the ideal position of the alignment mark can be performed by interpolation or extrapolation using a known method such as a least-squares method or an interpolation method from deviation amount data at the plurality of alignment mark positions. However, when the number of alignment marks is small or when the coordinates of the alignment mark position and the coordinates of each point in the shot region are sufficiently close to each other, the deviation amount of the alignment mark position can be used without conversion.

Coordinates when the parameters are changed with respect to the shot region A are defined as follows.
Shot region A right side: (XaRij+ΔXaRij′, YaRij+ΔYaRij′)

From the above, the following relational expression is obtained.

ΔXaRij′=ΔXaRij+Sx+XaRij*cos θ−YaRij*sin θ+XaRij*M+XaRij²*DX2+XaRij³*DX3+ΔXaRij+Sxj+XaRij*cos θj−YaRij*sin θj+XaRij*Mj+XaRij*Mj+XaRij²*DX2j+XaRij³*DX3j Expression 1

ΔYaRij′=ΔYaRij+Sy+XaRij*sin θ+YaRij*cos θ+YaRij*M+YaRij*My+YaRij²*DY2+YaRij³*DY3+ΔYaRij+Syj+XaRij*sin θj+YaRij*cos θj+YaRij*Mj+YaRij\hat{ }²*DY2j+YaRij³*DY3j Expression 2
where
Sx is an amount by which the shot region A is changed in the X direction,
Sy is an amount by which the shot region A is changed in the Y direction,
θ is an amount by which the shot region A is rotated about (0,0),
M is a magnification at which the shot region A is enlarged and reduced around (0,0),
My is a magnification at which the shot region A is enlarged and reduced in the Y direction around (0,0),
DX2 is an amount by which the X direction second-order distortion of the shot region A is changed,
DY2 is an amount by which the Y direction second-order distortion of the shot region A is changed,
DX3 is an amount by which the X direction third-order distortion of the shot region A is changed,
DY3 is an amount by which the Y direction third-order distortion of the shot region A is changed,
Sxj is an amount by which the exposure region at the Y=j position during scanning exposure is changed in the X direction,
Syj is an amount by which the exposure region at the Y=j position during scanning exposure is changed in the Y direction,
θj is an amount by which the exposure region at the position Y=j during scanning exposure is rotated about (0,0),
Mj is a magnification at which the exposure region at the position Y=j during scanning exposure is enlarged and reduced around (0,0),
DX2j is an amount by which the X direction second-order distortion of the exposure region at the Y=j position during scanning exposure is changed,
DY2j is an amount by which the Y direction second-order distortion of the exposure region at the Y=j position during scanning exposure is changed,
DX3j is an amount by which the X direction third-order distortion of the exposure region at the Y=j position during scanning exposure is changed, and
DY3j is an amount by which the Y direction third-order distortion of the exposure region at the Y=j position during scanning exposure is changed.

The conditions for improving the connection state at the connection portion between the shot regions can be written as follows.

ΔXaRij′=ΔXbij Expression 3

ΔYaRij=ΔYbij Expression 4

The lower side, the left side, and the upper side of the shot region A can also be considered similarly to the above. Therefore, the 17 correction amounts described above can be obtained by applying the relational expression to the four sides of the shot region A and solving, by the least-squares method, the expression in which the condition for improving the connection state at the connection portion between the shot regions is introduced into an objective function. This can determine the correction information based on the objective function representing the positional relationship of the points between the end portion of the shot region A and the end portions of the shot regions B to D.

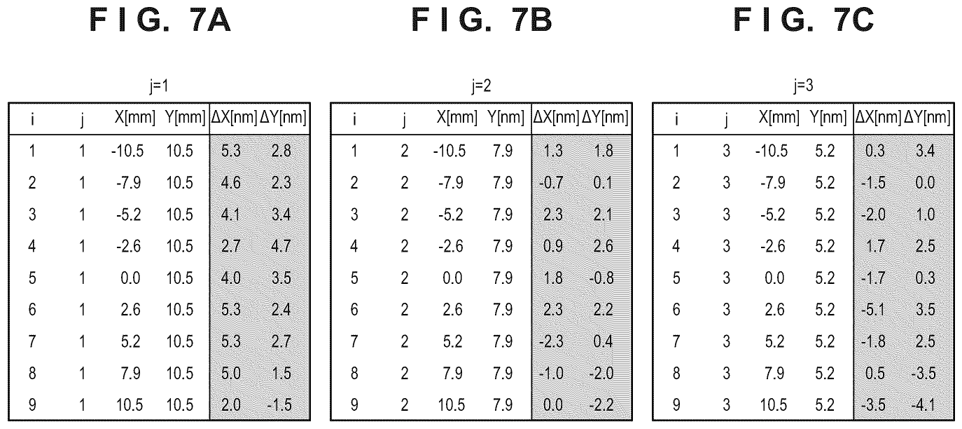

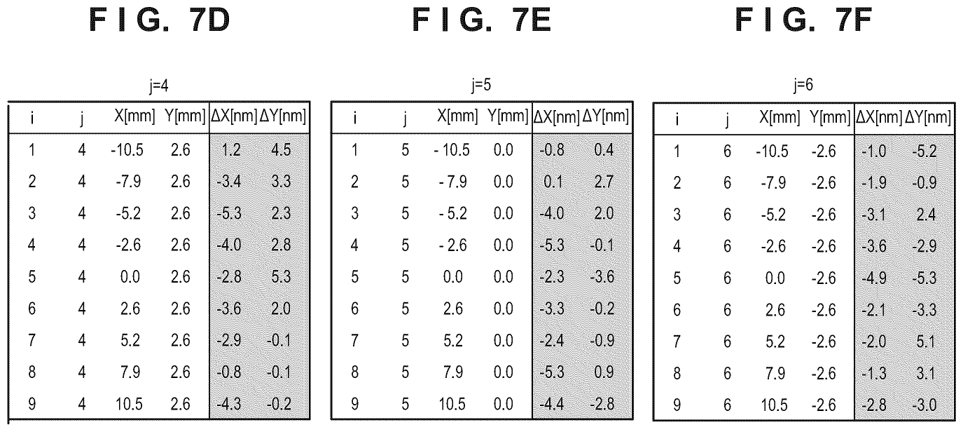

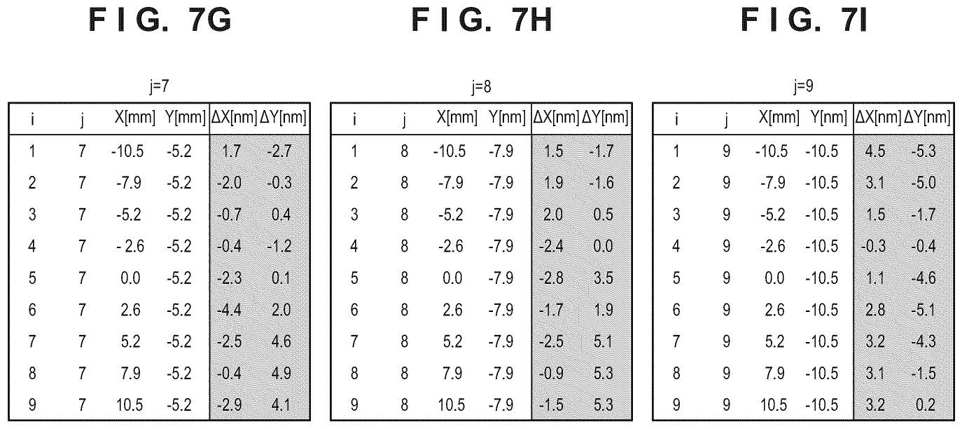

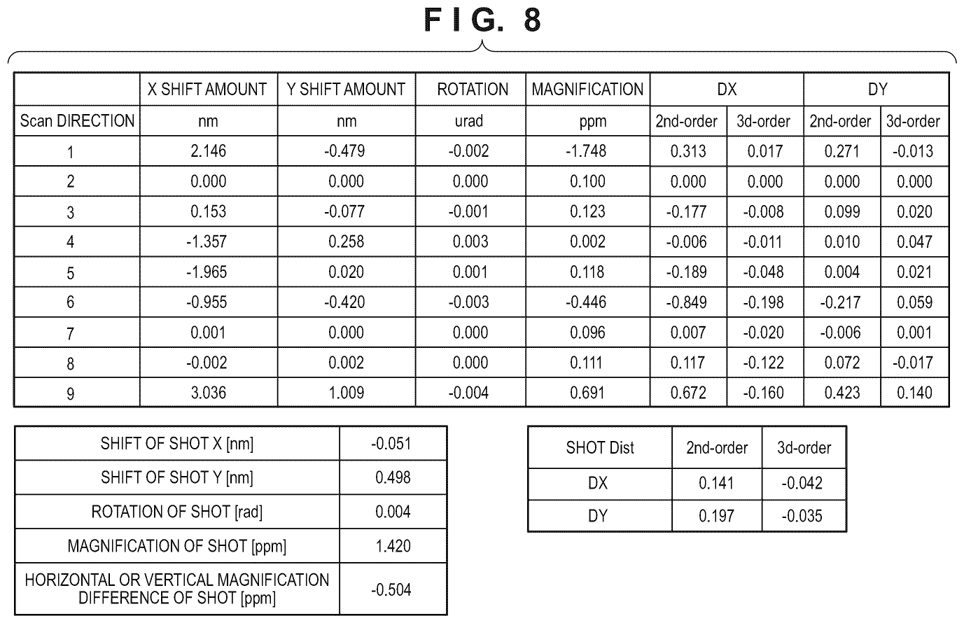

The shot region size of each of the shot regions A, B, C, D, and E was X=10.5 mm and Y=10.5 mm, and the initial coordinate value of the shot region A was set as illustrated in FIGS. 7A to 7I. Where, (X, Y)=(0,0) is the center of the shot region A. In FIGS. 7A to 7I, ΔX and ΔY represent deviation amounts from ideal coordinates. It is assumed that B, C, D, and E having the same shape as the shot region A are arranged on the upper, lower, left, and right of the shot region A. FIG. 8 illustrates an example of a calculation result of parameters for improving the connection state of the shot region by the above method.

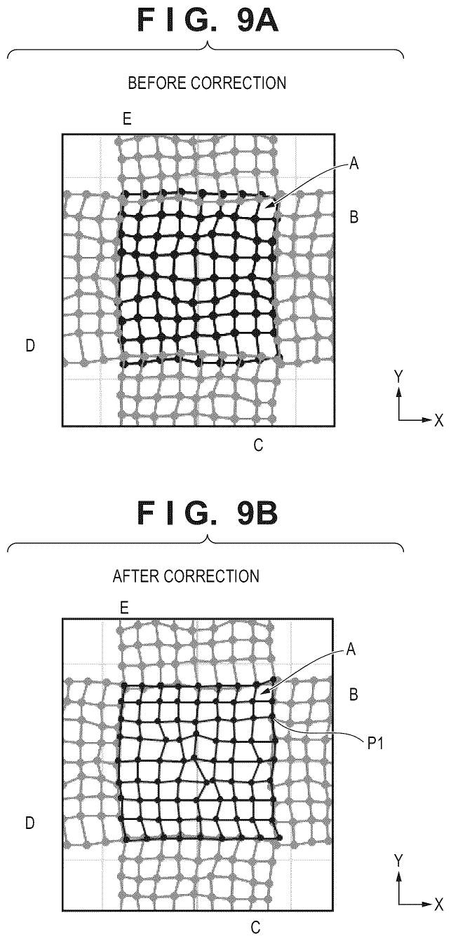

The relationship among the shot regions A, B, C, D, and E before the connection state of the shot region is improved is illustrated in FIG. 9A, and the relationship among the shot regions A, B, C, D, and E after the connection state of the shot region is improved according to the present example is illustrated in FIG. 9B. In FIGS. 9A and 9B, the black lines indicate the shot region A, and the gray lines indicate the peripheral shot regions B, C, D, and E. Note that in FIGS. 9A and 9B, the coordinate deviation is emphasized and plotted so that the relationship between the shot regions can be easily understood. By the stitching exposure illustrated in FIGS. 9A and 9B, for example, in the shot region A and the shot region B, the outer peripheral portions of the both match with each other at a point P1, for example. According to simulation, the distance between the adjacent points of the shot regions B, C, D, and E adjacent to the shot region A was 3.60 nm before the improvement, but was able to approach up to 1.30 nm after the improvement.

### Example 2

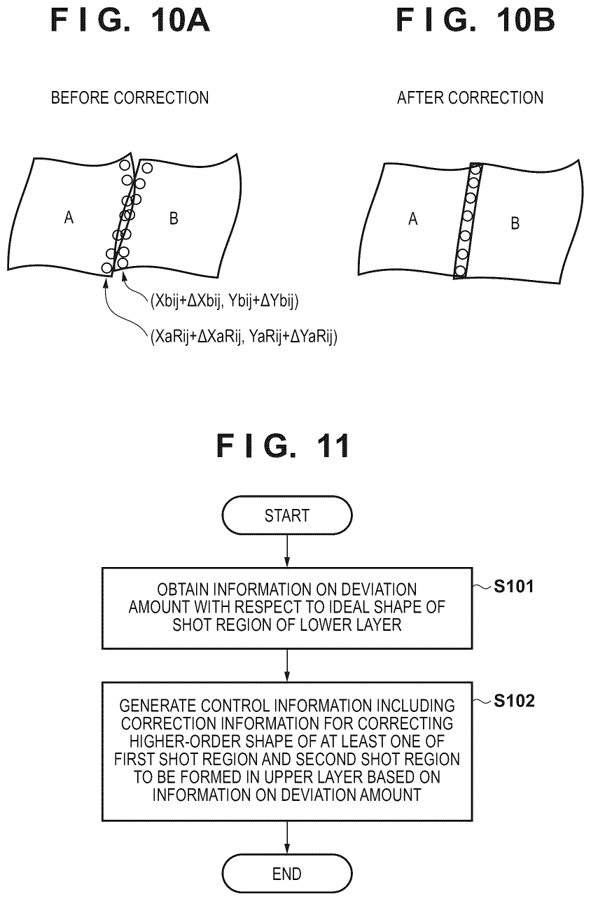

The operation flow of the exposure apparatus 100 in Example 2 is similar to that in FIG. 5. In Example 1 described above, improvement of the connection state of the shot regions when a plurality of adjacent shot regions are arranged without overlapping and without gaps has been described. In Example 2, improvement of a connection state of shot regions in a case where adjacent shot regions partially overlap will be described. FIG. 10A illustrates an example before the shot connection state is improved in a case where the shot region A and the shot region B adjacent to the shot region A are arranged in a partially overlapping state, and FIG. 10B illustrates an example after the shot connection state is improved. Similarly to Example 1, the coordinates of each point before improvement of the connection state between the shot region A and the shot region B are defined as follows.
Shot region A right portion (i=9, j=1 to 9): (XaRij+ΔXaRij, YaRij+ΔYaRij)
Shot region B left portion (i=9, j=1 to 9): (Xbij+ΔXbij, Ybij+ΔYbij)

In Example 1, the position to take the coordinates is taken on the side of the shot region, but in Example 2, the position is set so as to be included in the overlapping portion of the shot region A and the shot region B. The coordinates when parameters are changed with respect to the shot region A are obtained by the above-described Expressions 1 and 2. Here, the conditions for improving the connection region between the shot region A and the shot region B can be written as follows.

XaRij+ΔXaRij=Xbij+ΔXbij Expression 5

YaRij+ΔYaRij=Ybij+ΔYbij Expression 6

It is possible to obtain 17 correction amounts by solving, by the least-squares method, the expression in which the condition for improving the connection region of the shot is introduced into the objective function.

In the above examples, examples using the least-squares method have been described, but the present disclosure is not limited to this, and a known nonlinear optimization technique may be used.

### Second Embodiment

In the first embodiment described above, an example of improving the connection state with the adjacent shot region at the time of the first exposure in the exposing by the exposure apparatus 100 has been described. However, the present disclosure is not limited to this objective, and is also effective for the following problems.

In a known technique, in order to modify an arrangement error in first exposure, the overlay error is reduced by using “stage control during scanning” in the second exposure of the next layer. Here, “stage control during scanning” means that the relative position or the relative angle between the original stage and the substrate stage is adjusted in accordance with the exposure position in the scan direction. In the second exposure, in order to compensate for the arrangement error, after scanning is performed by a relative distance L in the scan direction (Y direction), the substrate stage is shifted by a distance ΔX in the non-scan direction (X direction), for example, and the remaining region is scanned. However, in practice, since the substrate stage control during scanning is discontinuous in the connection region of the shot region, the control cannot keep up, and an overlay error occurs not only in the connecting portion of the shot region but also in other regions. It is possible to reduce the control error of the substrate stage by slowing the scanning speed, but in this case, the throughput of the second exposure decreases. This problem can be solved by performing exposure so as to eliminate an arrangement error of the first exposure, but in a case where the shot region shape is deformed from the ideal shape, the connection state of the shot region becomes discontinuous even if there is no arrangement error.

According to the present embodiment, it is possible to improve the connection state of adjacent shots at the time of the first exposure in a case where the second exposure and the subsequent overlay exposure are performed in the shot region inclusive of the connection state of a plurality of shot regions. This can reduce an overlay error without reducing throughput.

### Embodiment of Article Manufacturing Method

The article manufacturing method in an embodiment of the present disclosure is suitable, for example, for manufacturing an article such as a microdevice (e.g., a semiconductor device) or an element having a microstructure. The article manufacturing method for the present embodiment includes transferring a pattern of an original to a substrate using the lithography apparatus described above (exposure apparatus, imprint apparatus, drawing apparatus, and the like), and processing the substrate to which the pattern has been transferred in the transferring. Furthermore, such the manufacturing method includes other well-known processes (oxidation, film formation, vapor deposition, doping, planarization, etching, resist peeling, dicing, bonding, packaging, and the like). The article manufacturing method of the present embodiment is advantageous in at least one of performance, quality, productivity, and production cost of an article as compared with known methods.

FIG. 11 illustrates a flowchart of a method for generating control information for the exposure apparatus 100 to perform the above-described stitching exposure. A program corresponding to this flowchart is included in the above-described control program, for example, and is executed by the main control system 101 (CPU 101a) as the information processing apparatus (computer). S101 and S102 in FIG. 11 correspond to the processing in S4 in FIG. 5 described above. In S101, the main control system 101 obtains information on the deviation amount with respect to the ideal shape of the shot region of the lower layer formed on the substrate (obtaining). In S102, the main control system 101 generates control information including correction information for correcting a higher-order shape of at least one of the first shot region and the second shot region to be formed in the upper layer based on the information on the deviation amount obtained in S101 (generating).

### OTHER EMBODIMENTS

Embodiment(s) of the present disclosure can also be realized by a computer of a system or apparatus that reads out and executes computer executable instructions (e.g., one or more programs) recorded on a storage medium (which may also be referred to more fully as a ‘non-transitory computer-readable storage medium’) to perform the functions of one or more of the above-described embodiment(s) and/or that includes one or more circuits (e.g., application specific integrated circuit (ASIC)) for performing the functions of one or more of the above-described embodiment(s), and by a method performed by the computer of the system or apparatus by, for example, reading out and executing the computer executable instructions from the storage medium to perform the functions of one or more of the above-described embodiment(s) and/or controlling the one or more circuits to perform the functions of one or more of the above-described embodiment(s). The computer may comprise one or more processors (e.g., central processing unit (CPU), micro processing unit (MPU)) and may include a network of separate computers or separate processors to read out and execute the computer executable instructions. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc (BD)™), a flash memory device, a memory card, and the like.

While the present disclosure has been described with reference to exemplary embodiments, it is to be understood that the present disclosure is not limited to the disclosed exemplary embodiments. The scope of the following claims is to be accorded the broadest interpretation so as to encompass all such modifications and equivalent structures and functions.

This application claims the benefit of Japanese Patent Application No. 2024-087246, filed May 29, 2024, which is hereby incorporated by reference herein in its entirety.

What is claimed is:

1. A computer-readable storage medium storing a program for causing a computer to execute a method for generating control information on a lithography apparatus that transfers a pattern to a substrate, wherein the lithography apparatus is configured to correct at least one of a first shot region and a second shot region of the substrate such that an outer peripheral portion of the first shot region and an outer peripheral portion of the second shot region match at least at one point, and
the program causes the computer to execute:
obtaining information on a deviation amount with respect to an ideal shape of a shot region of a lower layer formed on the substrate; and
generating control information including correction information for correcting a higher-order shape of the at least one of the first shot region and the second shot region to be formed at an upper layer based on information on the deviation amount.

2. The storage medium according to claim 1, wherein information on the deviation amount is information obtained by measuring a plurality of alignment marks on the substrate.

3. The storage medium according to claim 1, wherein a side of the at least one of the first shot region and the second shot region is not a linear shape with respect to a connection portion between the first shot region and the second shot region, and the correction information includes information for correcting a higher-order shape of a second or higher order of the side.

4. The storage medium according to claim 2, wherein
the lithography apparatus performs lithography processing of transferring a pattern to a test substrate and measures a plurality of alignment marks formed on the test substrate, and
in the obtaining, the computer obtains information on the deviation amount based on a result of the measurement.

5. The storage medium according to claim 1, wherein the correction information is determined based on an objective function representing a positional relationship of each point at an end portion of the first shot region and an end portion of the second shot region.

6. A lithography method comprising:
processing of transferring a pattern to a shot region of a substrate in accordance with control information, the processing including correcting at least one of a first shot region and a second shot region of the substrate such that an outer peripheral portion of the first shot region and an outer peripheral portion of the second shot region match at least at one point, wherein
the control information includes correction information for correcting a higher-order shape of at least one of the first shot region and the second shot region to be formed in an upper layer, the correction information being generated based on information on a deviation amount with respect to an ideal shape of a shot region of a lower layer formed on the substrate, and
transfer of the pattern is controlled based on the correction information.

7. The lithography method according to claim 6, wherein the correction is performed by correcting the at least one of the first shot region and the second shot region such that the first shot region and the second shot region are adjacent to each other without interposing a scribe line.

8. The lithography method according to claim 6, wherein a side of at least any of the first shot region and the second shot region is not a linear shape with respect to a connection portion between the first shot region and the second shot region, and the correction information includes information for correcting a higher-order shape of a second or higher order of the side.

9. The lithography method according to claim 6, wherein lithography processing of transferring a pattern to a test substrate is performed, a plurality of alignment marks formed on the test substrate are measured, and information on the deviation amount is obtained based on a result of the measurement.

10. The lithography method according to claim 6, wherein the correction information is determined based on an objective function representing a positional relationship of each point at an end portion of the first shot region and an end portion of the second shot region.

11. An information processing apparatus that generates control information on a lithography apparatus that transfers a pattern to a substrate, wherein the lithography apparatus is configured to correct at least one of a first shot region and a second shot region of the substrate such that an outer peripheral portion of the first shot region and an outer peripheral portion of the second shot region match at least at one point, and
the information processing apparatus includes:
an obtaining unit configured to obtain information on a deviation amount with respect to an ideal shape of a shot region of a lower layer formed on the substrate; and
a generation unit configured to generate control information including correction information for correcting a higher-order shape of the at least one of the first shot region and the second shot region to be formed at an upper layer based on information on the deviation amount.

12. A lithography apparatus that transfers a pattern to a substrate, comprising:
a control unit configured to perform control processing of performing transfer of the pattern by correcting at least one of a first shot region and a second shot region of the substrate such that an outer peripheral portion of the first shot region and an outer peripheral portion of the second shot region match at least at one point in accordance with control information, wherein
the control information includes correction information for correcting a higher-order shape of the at least one of the first shot region and the second shot region to be formed in an upper layer, the correction information being generated based on information on a deviation amount with respect to an ideal shape of a shot region of a lower layer formed on the substrate, and
the control unit controls formation of the pattern based on the correction information.

13. The lithography apparatus according to claim 12, wherein
the lithography apparatus is an exposure apparatus that transfers a pattern of an original to the substrate held by a substrate stage via a projection optical system, and
based on the correction information, the control unit controls at least any of the projection optical system and the substrate stage so as to adjust at least any of shift, rotation, magnification, distortion, and a horizontal or vertical magnification difference of the at least one of the first shot region and the second shot region.

14. The lithography apparatus according to claim 13, wherein
the exposure apparatus is a scanning exposure apparatus that exposes the substrate while scanning the original and the substrate, and
based on the correction information, the control unit controls at least any of the projection optical system and the substrate stage so as to adjust at least any of shift, rotation, magnification, distortion, and a horizontal or vertical magnification difference of the at least one of the first shot region and the second shot region, and shift, rotation, magnification, and distortion of the at least one of the first shot region and the second shot region during scanning exposure.

15. An article manufacturing method comprising:
transferring a pattern onto a substrate in accordance with the lithography method according to claim 6; and
processing the substrate having been subjected to the transferring, wherein
an article is obtained from the substrate having been subjected to the processing.
